(19) United States
(12) Patent Application Publication
(10) Pub. No.: US 2017/0279026 A1
(43) Pub. Date: Sep. 28, 2017

(54) THERMOELECTRIC MODULE

(71) Applicant: Mahle International GmbH, Stuttgart (DE)

(72) Inventors: Thomas Himmer, Reichenbach (DE); Christopher Laemmle, Stuttgart (DE)

(73) Assignee: Mahle International GmbH, Stuttgart (DE)

(21) Appl. No.: 15/506,727

(22) PCT Filed: Aug. 19, 2015
(86) PCT No.: PCT/EP2015/069014

§ 371 Date: May 31, 2017

(30) Foreign Application Priority Data
Aug. 26, 2014 (DE) 10 2014 216 974.7

(51) Int. Cl. H01L 35/32; H01L 35/20; H01L 35/10

(52) U.S. Cl. CPC H01L 35/32; H01L 35/10; H01L 35/20

(57) ABSTRACT

A thermoelectric module may include a metallic module housing surrounding a module interior and conductor bridges arranged therein. The module housing may include a cold side wall and a warm side wall connected to cold-side conductor bridges and warm-side conductor bridges, respectively, in a thermally conductive, electrically insulating and permanent manner. The module may also include thermoelectric elements extending between the cold-side and warm-side conductor bridges. The cold side wall may be formed from a first metal material having a first heat expansion coefficient, and the warm side wall may be formed from a second metal material having a second heat expansion coefficient distinct from the first heat expansion coefficient. At least one of the first and second metal materials may be an iron material, the wall formed from the iron material having an electrically insulating coating, including one of a glass-ceramic sol-gel, a silicon oxide, and a polysilazen coating.

### CROSS-REFERENCE TO RELATED APPLICATIONS

This application claims priority to International Patent Application No. PCT/EP2015/069014, filed on Aug. 19, 2015, and German Patent Application No. DE 10 2014 216 974.7, filed on Aug. 26, 2014, both of which are hereby incorporated by reference in their entirety.

### TECHNICAL FIELD

The present invention relates to a thermoelectric module.

### BACKGROUND

From DE 15 39 322 A1 a thermoelectric module is known which comprises a plurality of thermoelectric elements in the form of positively and negatively doped semiconductor materials, which are electrically interconnected by way of a plurality of conductor bridges. On its cold side, the thermoelectric module comprises a cold side wall, which is connected to a plurality of cold-side conductor bridges in a thermally conductive, electrically insulating and permanent manner. Analogously to this, the thermoelectric module on its warm side comprises a warm side wall which is connected to a plurality of warm-side conductor bridges in a thermally conductive, electrically insulating and permanent manner. The thermoelectric elements in this case are arranged between cold side and warm side wall so that they extend between the cold side and warm-side conductor bridges. In the case of the known thermoelectric modules, the cold side and the warm side wall are each formed by an aluminium block which are characterized by good heat conductivity and are arranged without mutual contact.

From DE 601 33 795 T2 a method for producing an electrically conductive layer on a dielectric surface is known. To this end, a substrate is treated with a solution containing bismuth ions. Following this, the substrate is treated with a sulphide solution. Finally, metal plating of the substrate is carried out.

To improve handling of such thermoelectric modules a metallic module housing can be provided which surrounds a module interior, in which the thermoelectric elements and the conductor bridges are arranged. The module housing then comprises the cold side wall and the warm side wall. The module housing can be sealed off hermetically, which substantially simplifies the handling, the assembly and the use of the thermoelectric modules.

Depending on the case of application, the thermoelectric modules can be exposed to a plurality of temperature changes which result in corresponding thermally induced expansion effects. When using encapsulated thermoelectric modules, which have a tightly sealed module housing, the thermal alternating loads can negatively affect the strength or the tightness of the module housing.

### SUMMARY

The present invention deals with the problem of stating an improved embodiment for a thermoelectric module comprising a module housing, which embodiment is characterized in particular by an increased service life.

According to the invention, this problem is solved through the subject of the independent claim. Advantageous embodiments are subject of the dependent claims.

The invention is based on the general idea of producing the cold side wall and the warm side wall of the module housing from different metal materials which preferentially differ from one another by different heat expansion coefficients. The invention in this case is based on the consideration that the different thermal loads on the cold side and on the warm side differ with respect to the temperature differentials that occur. By using different metal materials with different heat expansion coefficients, the thermal expansion effects on the side on which the temperature differentials are greater, can be reduced while on the side on which the temperature differentials that occur are lower, are greater compared with that. Combined, the absolute thermal expansion effects of the two walls can thereby be quasi synchronised as a result of which a differential of the expansion effects between the two walls can be reduced. To the same degree, thermally induced stresses between the warm side wall and the cold side wall can then also be reduced, which improves the longevity of the module housing and thus of the thermoelectric module.

Particularly advantageous here is an embodiment in which the cold side wall is formed from a first metal material, which comprises a first heat expansion coefficient, while the warm side wall is formed from a second metal material, which has a second heat expansion coefficient, which is smaller than the first heat expansion coefficient. This embodiment has proved to be advantageous for applications in which the maximum temperature differentials on the warm side are greater than on the cold side. Conceivable are for example vehicle applications of such thermoelectric modules in the case of which the warm side is coupled in a heat-transmitting manner to an exhaust line of an internal combustion engine of the vehicle while the cold side is coupled in a heat-transmitting manner to a cooling circuit of the vehicle. The exhaust gas temperatures in this case fluctuate in a significantly greater ranger than the coolant temperatures.

According to an advantageous further development, the first heat expansion coefficient can be greater by at least 25%, preferentially at least 50%, in particular at least 100% than the second heat expansion coefficient. Because of this, the thermal stresses due to thermal alternating loads between the warm side wall and the cold side wall can be significantly reduced.

According to another further development, the first metal material can be an aluminium material. As aluminium material, both aluminium metal and also an aluminium alloy are possible. In addition or alternatively, the second metal material can be a titanium material. As titanium material, both titanium metal and also a titanium alloy are possible. The heat expansion coefficient of aluminium is significantly greater than the heat expansion coefficient of titanium. Furthermore, the heat expansion coefficient of aluminium is greater than that of iron, while the heat expansion coefficient of titanium is smaller than that of iron. Consequently, the following combinations are initially possible for the module housing. According to a first possibility, the cold side wall consists of an aluminium material while the warm side wall consists of a titanium material. According to a second possibility, the cold side wall again consists of an aluminium material while the warm side wall now consists of an iron material. According to a third possibility, the cold side wall now consists of an iron material, while the warm side wall consists of a titanium material. Possible iron materials are especially steel materials, in particular stainless steel materials.

Furthermore, austenitic iron materials on the one hand and ferritic iron materials on the other hand are possible as iron material, which in each case can again be configured as steel or stainless steel. A ferritic iron material, which can also be called ferrite in the following, has a significantly lower heat expansion coefficient than an austenitic iron material, which can also be called austenite. Thus, the cold side wall, according to an advantageous embodiment, can be practically formed by a austenite while it can be advantageous for the warm side wall to produce the same from a ferrite. Thus, the aforementioned three possibilities can be optimised.

However, another embodiment is also alternatively conceivable, in which the two side walls are each produced from an iron material, the first metal material for the cold side then being an austenite while the second metal material for the warm side is then being a ferrite.

In an embodiment, in which the first metal material is an aluminium material, the cold side wall can comprise an electrically insulating anodised layer, which can substantially consist of aluminium oxide. In the case that the second metal material is a titanium material, the warm side wall can comprise an electrically insulating anodised layer which can substantially consist of titanium oxide and is also described as hard coat. With the help of such an anodised layer, an efficient electrical insulation between the respective side wall and the conductor bridges can be realised in a particularly simple manner, which is additionally characterized by a relatively low thermal resistance.

In an embodiment, in which the first metal material is an iron material, the cold side wall can comprise an electrically insulating glass-ceramic sol-gel coating. Alternatively, a silicon (di) oxide or polysilazen coating is also conceivable here. Additionally or alternatively the warm side wall, in an embodiment, in which the second metal material is an iron material, can comprise an electrically insulating glass-ceramic sol-gel coating. Alternatively, a silicon (di) oxide or polysilazen coating is also conceivable here. Such a coating can be particularly easily applied onto the respective side wall of an iron material and is characterized on the one hand by an efficient electrical insulation and on the other hand by a low thermal resistance, i.e. by a relatively good heat conductivity.

According to a further development, the conductor bridges can be thermally sprayed on the respective anodised layer or onto the respective sol-gel coating. Spraying on the conductor bridges can be particularly easily realised as part of large series production without damage of the respective anodised layer or the sol-gel coating occurring in the process.

According to a further development, the conductor bridges can be sprayed on in multiple layers and accordingly comprise a first layer consisting of an aluminium material or of a titanium material or of an iron material sprayed onto the respective anodised layer or onto the respective sol-gel coating and a second layer of a copper material or of a nickel material sprayed onto the first layer. Because of two-layer nature of the sprayed-on conductor bridges, the fatigue strength of the connection between the conductor bridges and the respective side wall or the respective anodised coating or sol-gel coating can be substantially improved. By suitably selecting the material for the first layer, the heat expansion coefficient of the first layer can be selected equal to or approximately equal to that of the associated side wall. Selecting the metal materials for the second layer, which is sprayed onto the first layer, is performed so that connecting of the conductor bridges to the thermoelectric elements is simplified. Usually, the thermoelectric elements are soldered to the conductor bridges. A reliable soldered connection can be achieved for example in particular when the second layer consists of a copper material or nickel material. It is additionally conceivable, furthermore, to apply a third layer consisting of a nickel material onto the second layer consisting of a copper material, in order to create a diffusion barrier.

In another embodiment it can be provided that the conductor bridges are configured as separate components and are glued onto the respective anodised layer or onto the respective sol-gel coating. Such an embodiment can also be realised comparatively cost-effectively.

In another embodiment it can be provided that onto the respective anodised layer or onto the respective sol-gel coating a metal layer is applied at least in the region of the respective conductor bridges. The respective conductor bridge can then be galvanised onto this metal layer or be configured as separate component and soldered onto the respective metal layer. This embodiment is also characterized by a reliable fixing of the conductor bridges to the respective side wall and by a simplified connecting of the conductor bridges to the thermoelectric elements.

According to a further development, the respective metal layer can be galvanised on or printed on and burned into the anodised layer or onto the sol-gel coating at least in the region of the conductor bridges or be applied by means of a CVD method or by means of a PVD method. CVD stand for chemical vapour deposition and describes a chemical gas phase deposition. PVD stands for physical vapour deposition and describes a physical gas phase deposition. During the PVD method, the raw material which is to be deposited is in a solid state while with the CVD method it is in a gaseous state.

Alternatively, the conductor bridges can be printed on and burnt into the respective anodised layer or the respective sol-gel coating which can be cost-effectively realised within the scope of a series production.

According to another advantageous embodiment, the cold side wall, along an edge surrounding the housing interior between cold side and warm side in a circumferential direction can be directly soldered to the warm side wall.in an extreme case, the module housing then comprises only the warm side wall and the cold side wall, which are soldered together and form the module housing.

Alternatively it can be provided that between the cold side wall and the warm side wall in the region of an edge surrounding the housing interior between cold side and warm side in a circumferential direction a separate connection frame is provided, which is soldered to the cold side wall and to the warm side wall. With this embodiment the module housing thus consists of three components, namely of the cold side wall, the warm side wall and the connecting frame. With this embodiment, the side walls can be realised particularly easily and thus cost-effectively with respect to their geometry.

In another embodiment, the cold side wall can comprise a cold side frame which along an edge surrounding the housing interior between the cold side and the warm side in a circumferential direction surrounds the module housing in a closed manner and is attached to the cold side wall. Analogously to this, the warm side wall can comprise a warm side frame which along the edge runs around in a closed manner and is attached to the warm side wall. The cold side frame can now be soldered to the warm side frame in order to tightly seal the module housing. With this embodiment, the side walls can also have a comparatively simple construction as a result of which they can be produced cost-effectively. With the help of the respective side frame, the conductor bridges and the thermoelectric elements can be more easily positioned when producing the thermoelectric modules.

In an advantageous further development, the cold side frame like the respective cold-side conductor bridges can be attached to the cold side wall. The same then practically also applies to the warm side frame which accordingly, like the respective warm-side conductor bridges, can be attached to the warm side wall. For attaching the respective side frame to the respective side wall, reference can thus be made to the versions for attaching the conductor bridges to the side walls explained above, such as for example gluing on, galvanising on, printing on, spraying on.

Further important features and advantages of the invention are obtained from the subclaims, from the drawings and from the associated figure description by way of the drawings.

It is to be understood that the features mentioned above and still to be explained in the following cannot only be used in the respective combination stated but also in other combinations or by themselves without leaving the scope of the present invention.

Preferred exemplary embodiments of the invention are shown in the drawings and are explained in more detail in the following description, wherein same reference characters relate to same or similar or functionally same components.

### BRIEF DESCRIPTION OF THE DRAWINGS

It shows, in each case schematically

FIG. 1 a highly simplified cross section of a thermoelectric module,

FIGS. 2 to 7 in each case a cross section of a cold side wall of the thermoelectric module with different embodiments,

FIGS. 8 to 13 in each case a cross section of a warm side wall of the thermoelectric module with different embodiments,

FIGS. 14 and 15 in each case an isometric view of a side wall of the thermoelectric module with different embodiments,

FIGS. 16 to 18 in each case a cross section of the thermoelectric module in an edge region of a module housing with different embodiments.

### DETAILED DESCRIPTION

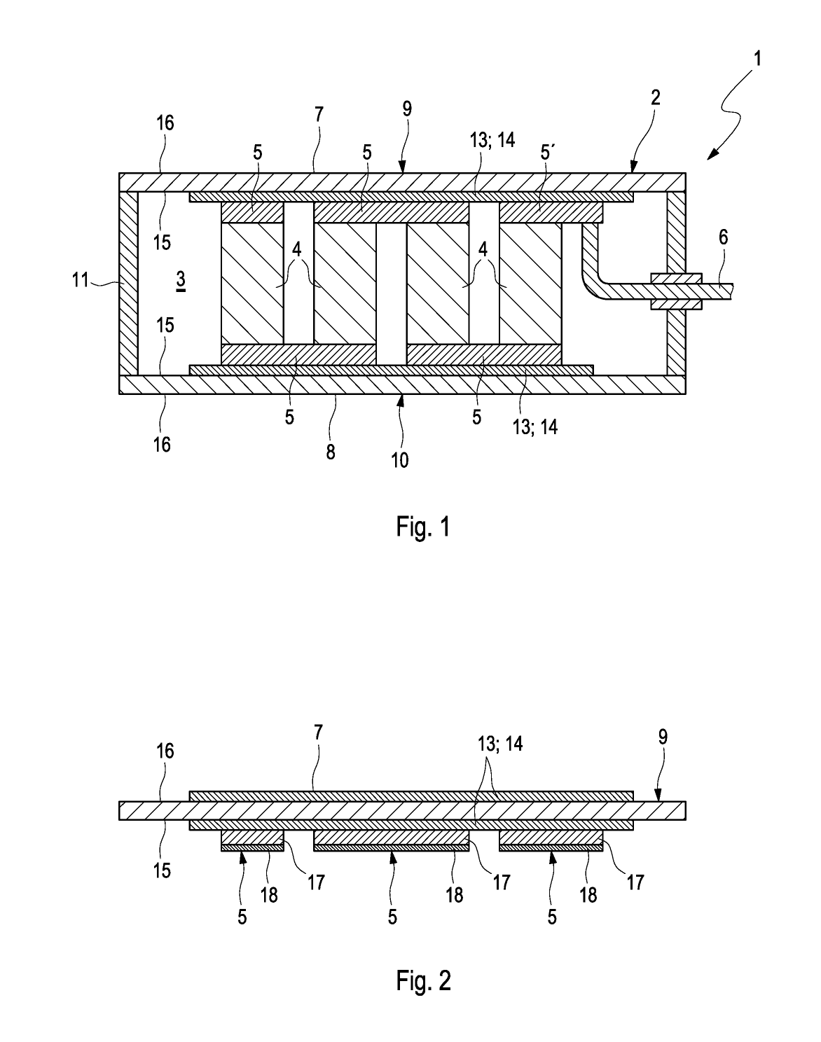

According to FIG. 1, a thermoelectric module 1 comprises a metallic module housing 2, which surrounds a module interior 3. In the module interior 3, a plurality of thermoelectric elements 4 are arranged, which are semiconductor elements, which are generally alternately P-doped, i.e. positively doped and N-doped, i.e. negatively doped. In the module interior 3, a plurality of electrically conductive conductor bridges 5 is arranged, with the help of which the thermoelectric elements 4 are electrically interconnected. In particular, such conductor bridges 5 connect a P-doped thermoelectric element 4 with an adjacent N-doped thermoelectric element 4. With the help of the conductor bridges 5, multiple thermoelectric elements 4 are connected in series. Likewise, multiple series connections of the thermoelectric elements 4 can be connected in parallel with the help of the conductor bridges 5. In addition, two such conductor bridges 5 can also serve for connecting an electrical contact 6. Such a connection conductor bridge 1 is marked with 5′ in FIG. 1. Each thermoelectric module 1 comprises at least two such thermoelectric contacts 6, namely for a negative pole connection and a positive pole connection. In FIG. 1, only one of the contacts 6 is visible.

Interconnecting the thermoelectric elements 4 with the help of the conductor bridges 5 is usually carried out in such a manner that on the electrical contacts 6 of the module 1 an electrical voltage is created when between a cold side 7 of the module 1 and a warm side 8 of the module 1 a temperature differential occurs. Thus, the thermoelectric modules 1 utilise the so-called Seebeck effect, which corresponds to an inversion of the Peltier effect.

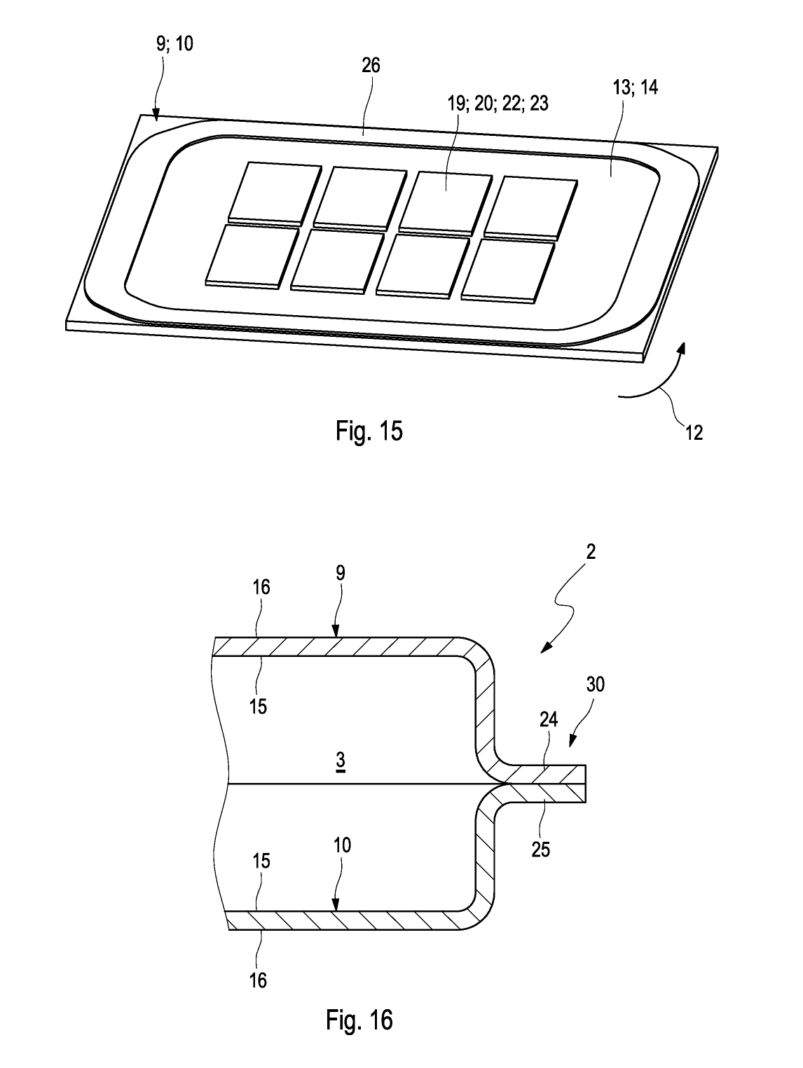

On its cold 7, the module housing 2 comprises a cold side wall 9 which is connected to a plurality of cold-side conductor bridges 5 in a heat-conductive, electrically insulating and permanent manner. The thermoelectric elements 4 extend geometrically between the cold-side and warm-side conductor bridges 5. In the example of FIG. 1, a connecting frame 11 is additionally provided between the cold side wall 9 and the warm side wall 10, which surrounds the housing interior 3 between the cold side 7 and the warm side 8 in a circumferential direction 12 indicated in the FIGS. 14 and 15 by a double arrow surrounding the edge region. The connecting frame 11 in the example of FIG. 1 is configured as a separate component with respect to the cold side wall 9 and with respect to the warm side wall 10 and connected permanently to both side walls 9, 10 in a suitable manner, in particular soldered to these.

In the module 1 introduced here, the cold side wall 9 is produced from a first metal material which has a first heat expansion coefficient. The warm side wall 10, by contrast, is produced from a second metal material that is distinct from the first metal material, which has a second heat expansion coefficient which differs from the first heat expansion coefficient. Accordingly, the first heat expansion coefficient is either greater or smaller than the second heat expansion coefficient. Preferred is an embodiment, in which the first heat expansion coefficient is greater than the second heat expansion coefficient. The greater first heat expansion coefficient is thus assigned to the cold side wall 9 while the smaller second heat expansion coefficient is assigned to the warm side wall 10. For example, the first heat expansion coefficient is at least 25% greater than the second heat expansion coefficient. Preferably, the first heat expansion coefficient is at least 50% greater than the second heat expansion coefficient. Particularly advantageous is an embodiment, in which the first heat expansion coefficient is at least twice as great as the second heat expansion coefficient.

The first metal material, from which the cold side wall 9 is produced, is preferably an aluminium material, while the second metal material, of which the warm side wall 10 consists, is preferably a titanium material. Accordingly, a cold side wall 9 of aluminium is preferably combined with a warm side wall 10 of titanium in the module housing 2. In another advantageous embodiment, a cold side wall 9 of an austenitic iron material is combined with a warm side wall 10 of a ferritic iron material in the module housing 2. With the aluminium-titanium combination, the first heat expansion coefficient is more than twice as great as the second heat expansion coefficient. In the case of the austenite-ferrite combination, the first heat expansion coefficient is approximately 50% greater than the second heat expansion coefficient.

It is clear that other material combinations within the module housing 2 are also conceivable for as long as there is an adequate differential between the heat expansion coefficients of the two side walls 9, 10. For example, a cold side wall 9 of aluminium can be combined with a warm side wall 10 of iron. Likewise, a cold side wall 9 of iron can be combined with a warm side wall 10 of titanium.

As is evident from FIG. 1, the two side walls 9, 10 of the module housing 2 are each provided, at least on a side facing the module interior 3, with a coating 13 or 14, which is arranged between the respective side wall 9, 10 and the associated conductor bridges 5. The coating 13 or 14 is configured so that on the one hand it brings about an electrical insulation and on the other hand ensures a relatively good heat conductivity between the respective side wall 9, 10 and the respective associated conductor bridges 5.

Provided that for the cold side wall 9 an aluminium material is used as metal material, the coating is preferably an anodised layer 13. When the cold side wall 9, by contrast, is produced from an iron material, in particular from an austenite, the coating is preferably a sol-gel coating 14. When the warm side wall 10 is produced from a titanium material, the anodised layer 13 is again preferred. When by contrast the warm side wall 10 is produced from an iron material, preferably from a ferrite, a sol-gel coating 14 is again preferred. The following description of specific embodiments by way of the FIGS. 2 to 13 uses these preferred embodiments as a base so that whenever the cold side wall 9 is produced from aluminium material, an anodised layer 13 is present. When the cold side wall 9, by contrast, is produced from an iron material, a sol-gel coating 14 is present.

Then, similar applies also to the warm side wall 10. If the side wall 10 is produced from a titanium material, an anodised layer 13 is present. When the warm side wall 10 by contrast is produced from an iron material, a sol-gel coating 14 is present.

Initially it is evident from the FIGS. 2 to 13 that it is practical to provide the respective side wall 9, 10 both on its inside 15 facing the module interior 3 and also on its outside 16 facing away from the module interior 3 with such a coating 13 or 14, as a result of which the module housings 2 are electrically insulating in this respect, for example in order to contact them with metallic heat sources.

In the embodiment shown in FIG. 2, the conductor bridges 5 are thermally sprayed onto the respective coating 13 or 14, i.e. either onto the anodised layer 13 or onto the sol-gel coating 14. Here, a usual thermal spraying method is employed, i.e. for example cold gas spraying or plasma spraying. For this purpose it can be necessary in advance to suitably prepare the respective side wall 9, 10 for example by sandblasting and/or heating. For spraying on the cold-side conductor bridges 5, a metal material is preferred which has a heat expansion coefficient that is similar to that of the cold side wall 9. When the cold side wall 9 is produced for example from an aluminium material, an aluminium material is also used for the cold-side conductor bridges 5.

In the example of FIG. 2, the conductor bridges 5 are sprayed on in two layers, wherein a first layer 17 is directly sprayed onto the respective coating 13 or 14, while a second layer 13 is subsequently sprayed onto the first layer 17. The first layer 17 is matched to the cold side wall 9 with respect to the heat expansion coefficient while the second layer 18 is selected with respect to as simple as possible a connection with the thermoelectric elements 4. For example, the second layer 18 can be produced from a copper material or from a nickel material, which simplifies the reduction of soldered connections.

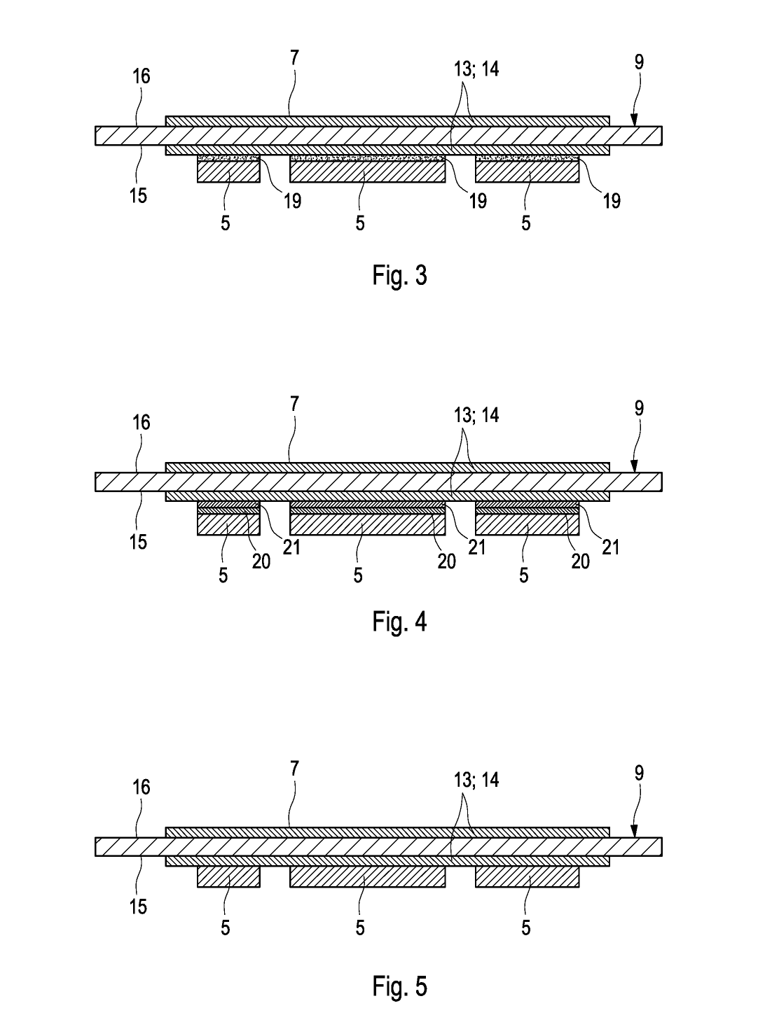

In the embodiment shown in FIG. 3, the conductor bridges 5 are provided in the form of separate components, which are glued onto the respective coating 13 or 14 in a suitable manner. In FIG. 3, a corresponding adhesive layer is marked with 19.

In the embodiment shown in FIG. 4, a metal layer 20 is initially applied in each case onto the respective coating 13 or 14 at least in the region of the cold-side conductor bridges 5. This metal layer 20 can, in principle, be directly applied onto the respective coating 13 or 14. However in FIG. 4 a preferred embodiment is shown, in which an activation layer 20 or adhesive base layer 21 is applied onto the respective coating 13 or 14 in advance, onto which the respective metal layer 20 is then applied. The conductor bridges 5 can then be galvanised for example onto the metal layer 20. It is likewise possible to solder the conductor bridges 5 in the form of separate components onto the metal layer 20.

The metal layer 20 in turn can be galvanised onto the respective coating 13 or 14 or onto the respective activation layer 21. It is likewise possible to print on and burn the metal layer 20 into the coating 13 or 14 or the activation layer 21. Here, a simple screen printing method can be employed. Alternatively it is likewise possible to apply the metal layer 20 by means of a CVD method or by means of a PVD method onto the coating 13 or 14 respectively or onto the respective activation layer 21.

FIG. 5 shows an embodiment, in which the conductor bridges 5 are directly printed onto the respective coating 13 or 14. As printable, pasty conductor bridge material, a mixture of metal particles, glass particles and a suitable binder are employed for example. Following the application of the pasty conductor bridge material, for example by way of the screen printing method, burning-in takes place, during which the glass particles bond with the anodised layer 13 or with the sol-gel coating 14, while the binder mixture evaporates. A porous yet solid metallic conductor bridge structure for example of copper or on a copper basis remains, which via the glass components is permanently connected to the respective coating 13 or 14. At the same time, this metallic conductor bridge structure is suitable in a special way for producing a soldered connection with the thermoelectric elements 4.

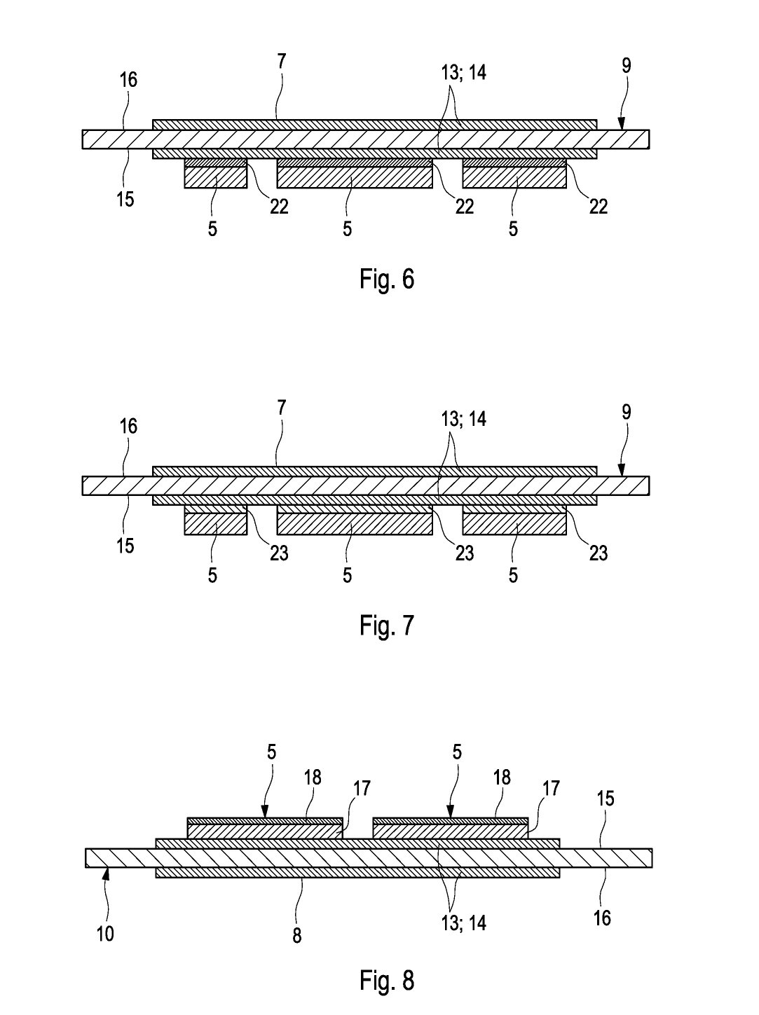

In the embodiment shown in FIG. 6, the conductor bridges 5 provided as separate bodies are permanently connected to the respective coating 13 or 14 via a metallic coating structure 22 or metal layer 22. This coating structure 22 can be applied and burned in on the respective coating 13, 14 in the form of a pasty coating material. For example, this pasty coating material consists of a mixture of metal particles, glass particles and a binder mixture which is printable and can be applied to the respective coating 13, 14 for example by means of silk screen printing. By burning-in, the glass particles of the coating paste bond with the respective coating 13 or 14 while the binding mixture evaporates. The solid metallic coating structure 22 then remains, which can for example comprise copper or a copper alloy as metal component.

Finally, FIG. 7 shows an embodiment in which a metal coating 23 is likewise directly applied onto the respective coating 13 or 14 by means of CVD method or by means of PVD method. Onto this metal layer 23, the conductor bridges 5 which are configured as separate components can then be applied, for example by means of a soldering method. Alternatively, the conductor bridges 5 can also be galvanised onto this metal layer 23.

While the FIGS. 2 to 7 present versions for configuring the cold side wall 9 or version for producing the cold side wall 9, the FIGS. 8 to 13 analogously thereto show configurations of the warm side wall 10 or methods that are analogous thereto for producing the warm side wall 10.

Accordingly, FIG. 8, analogously to FIG. 2, shows an embodiment in which the warm-side conductor bridges 5 are thermally sprayed onto the respective coating 13 or 14. Again shown is a two-layer configuration of the conductor bridges 5. The first layer 17 can be produced, in principle, from an aluminium material, but it is preferably a material which has a heat expansion coefficient that is similar to the warm side wall 10. Accordingly, the use of a titanium material or of a ferritic iron material for the first layer 17 of the warm-side conductor bridges 5 is conceivable for example. The second layer 18 is sprayed onto the first layer 17 and is characterized by a favourable connectability to the thermoelectric elements 4. For example, the second layer 18 is produced from a metal material on copper bases or nickel bases so that it can be easily soldered to the thermoelectric elements 4.

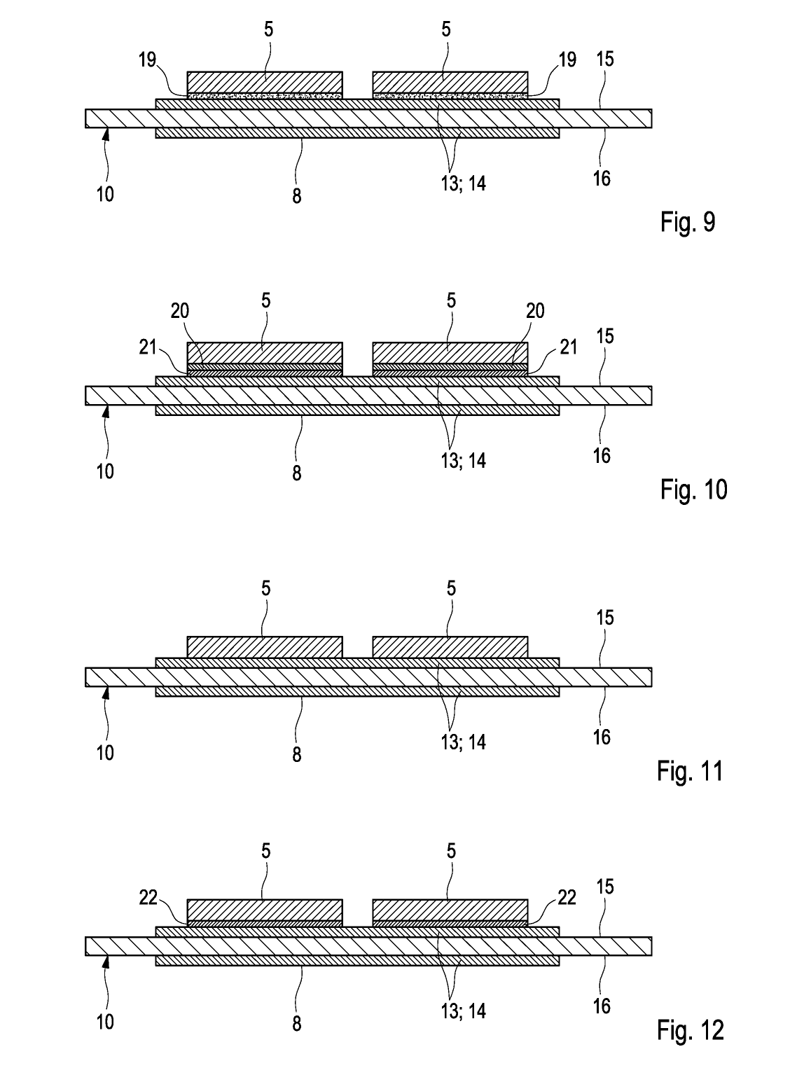

According to FIG. 9, which is configured analogous to the version of FIG. 3, the warm-side conductor bridges 5 can be glued onto the respective coating 13 or 14 of the warm side wall 10 in the form of separate bodies. A corresponding adhesive layer is likewise marked with 19 in FIG. 9.

FIG. 10 shows a configuration analogous to FIG. 4, in which a metal layer 20 is applied. This can be applied either directly onto the respective coating 13 or 14. However, an embodiment in which initially a prime layer or activation layer 21 is initially applied directly onto the respective coating 13 or 14 while the aforementioned metal layer 20 is then applied onto this activation layer 21. Here, too, the activation layer 21can be formed for example from palladium, while seeding in acid with ionogenic metalisation and upstream pickling and activation steps can be employed. Following this, an etching step can be required in order to remove excess coating material. The warm-side conductor bridges 5 can then be soldered onto the metal layer 20 for example in the form of separate bodies. For example, a tin-containing solder can be employed here.

Analogously to FIG. 5, FIG. 11 shows a version in which the warm-side conductor bridges 5 are applied to and burned into the respective coating 13 or 14 in the form of a pasty compound. Here, a pasty conductor bridge material that is printable for example by means of screen printing technology can also be employed. This conductor bridge base can comprise a mixture of metal particles, glass particles and a binder or binder mixture. The glass components create the connection with the coating 13 or 14 while the metal particles make possible good solderability to the thermoelectric elements 4.

FIG. 12 substantially corresponds to FIG. 6. Accordingly, a metal layer 22 is printed and burned in onto the respective coating 13, 14 of the warm side wall 10. Following this, the conductor bridges 5 provided in the form of separate bodies can be galvanically soldered onto the metal layer 22.

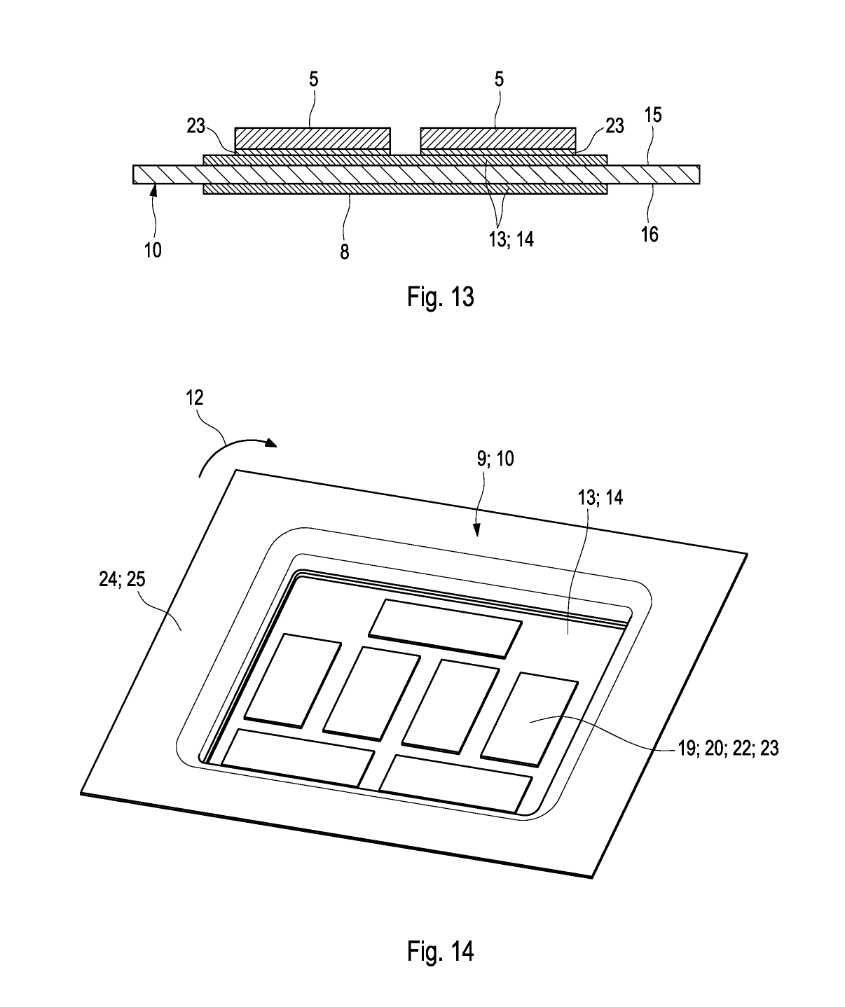

FIG. 13 now largely corresponds to FIG. 7 and accordingly shows an embodiment in which a metal coating 23 is applied, at least in the region of the warm-side conductor bridges 5, onto the respective coating 13 or 14 of the warm side wall 10 by means of a CVD method or by means of a PVD method. Following this, the conductor bridges 5 can be soldered onto the metal coating 23 in the form of separate bodies. It is likewise conceivable to apply the warm-side conductor bridges 5 onto the respective metal layer 23. Galvanising in this case can be realised with current or without current.

The FIGS. 14 and 15 each show one of the side walls 9, 10, wherein within the module housing 2 at least one of the side walls 9, 10 is configured according to FIG. 14 or according to FIG. 15. Practical are embodiments in which either both sides walls 9, 10 are configured according to FIG. 14 or according to FIG. 15.

According to FIG. 14, the respective side wall 9, 10 comprises a stepped edge 24 (for the cold side wall 9) or 25 (for the warm side wall 10). This edge 24 or 25 runs around in the circumferential direction 12 in a closed manner about the housing interior 3, in which the conductor bridges 5 are arranged.

In the embodiment shown in FIG. 15, the respective side wall 9 or 10 is configured as a flat metal sheet, i.e. as a two-dimensional structure. Noticeable is a circumferential surround 26 which is closed in the circumferential direction 12, which likewise surrounds the module interior in which the conductor bridges 5 are arranged. The conductor bridges 5 are not shown here, while the adhesive layer 19 of the FIGS. 3 and 9, the metal coating of the FIGS. 4 and 10, the metal coating 22 of the FIGS. 6 and 12 and the metal coating 23 of the FIGS. 7 and 13 are visible. Practically, the surround 26 has the same structure as the mentioned layers 19, 20, 22, 23, which are employed with the respective side wall 9 or 10 in order to fix the conductor bridges 5 thereon.

According to FIG. 16, the cold side wall 9 and the warm side wall 10 can be soldered directly to one another along the previously mentioned steps 24 and 25. The module housing 2 then substantially consists only of the cold side wall 9 and the warm side wall 10.

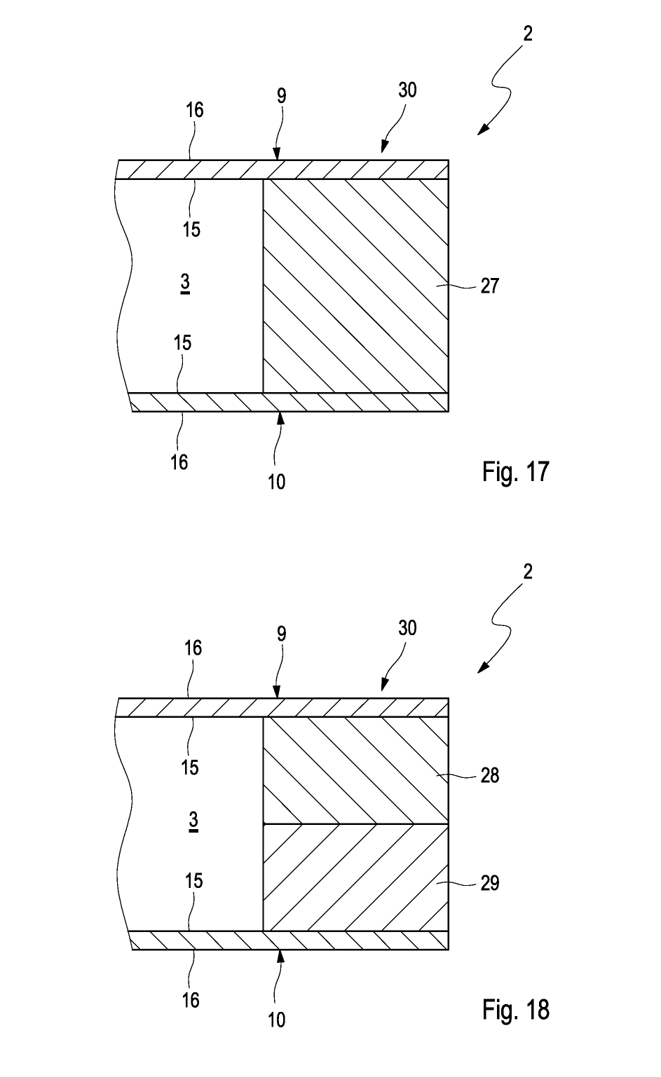

In the embodiment shown in FIG. 17, a connecting frame 27 that is separate with respect to the side walls 9, 10 is provided between the cold side wall 9 and the warm side wall 10 in the region of the edge region 30 circulating in the circumferential direction 12, which on the one hand is soldered to the cold side wall 9 and on the other hand to the warm side wall 10. The connecting frame 27 is practically configured completely closed circumferentially in the circumferential direction 12. The electrical contacts 6 are suitably passed through the connecting frame 27. In this case, the module housing 2 substantially consists of the two side walls 9, 10 and the connecting frame 27.

Finally, FIG. 18 shows an embodiment in which the cold side wall 9 comprises a cold side frame 28 which in the edge region along the circumferential direction runs around in a closed manner and surrounds the housing interior 3. In this case, the warm side wall 10 is also equipped with a warm side frame 29 which runs around along the circumferential direction 12 about the module interior 3 in a closed manner. The cold side frame 28 is practically soldered to the warm side frame 29. In principle, the cold side frame 28 can be soldered to the cold side wall 9. Likewise, the warm side frame 29 can be soldered to the warm side wall 10. However the embodiment indicated in FIG. 15 is preferred, in which the cold side frame 28 like the cold-side conductor bridges 5 is attached to the cold side wall 9. Likewise, the warm side frame 29, like the warm-side conductor bridges 5, can be attached to the warm side wall 10. In particular, the surround 26 indicated in FIG. 15 can also be employed, which can be formed for example by an adhesive layer 19 or by a metal layer 20 or 22 or 23, with the help of which the respective conductor bridges 5 can also be fastened to the respective side wall 9 or 10. In these cases, the respective coating 13 or 14 is then realised as far as to the edge of the respective side wall 9, 10 which simplifies the production. Provided that the respective frame 28, 29 just as the connecting frame 27 is soldered to the associated side wall 9, 10, the respective coating 13, 14 then extends at least on the respective inside 15 practically not as far as to the edge of the respective side wall 9, 10 but the edge region 30 in particular remains free of the respective coating 13, 14.

1. A thermoelectric module, comprising:
a metallic module housing that surrounds a module interior,
a plurality of thermoelectric elements arranged in the module interior; and
a plurality of conductor bridges arranged in the module interior for electrically interconnecting the thermoelectric elements;
wherein the module housing has a cold side wall on a cold side, the cold side wall being connected to a plurality of cold-side conductor bridges in a thermally conductive, electrically insulating and permanent manner;
wherein the module housing has a warm side wall on a warm side, the warm side wall being connected to a plurality of warm-side conductor bridges in a heat-conductive, electrically insulating and permanent manner;
wherein the thermoelectric elements extend between the cold-side conductor bridges and the warm-side conductor bridges;
wherein the cold side wall is formed from a first metal material and the warm side wall is formed from a second metal material;
wherein the first metal material has a first heat expansion coefficient and the second metal material has a second heat expansion coefficient;
wherein the second heat expansion coefficient is distinct from the first heat expansion coefficient
wherein at least one of the first metal material and the second metal material is an iron material, at least one of the cold side wall and the warm side wall formed from the iron material having an electrically insulating coating, including one of a glass-ceramic sol-gel coating, a silicon (di) oxide coating, and a polysilazen coating.

2. The module according to claim 1, wherein:
the first metal material is an iron material, and the cold side wall has an electrically insulating coating, including one of a glass-ceramic sol-gel coating, a silicon (di) oxide coating, and a polysilazen coating; and
the second metal material is an iron material, and the warm side wall has an electrically insulating coating, including one of a glass-ceramic sol-gel coating, a silicon (di) oxide coating, and a polysilazen coating.

3. The module according to claim 1, wherein:
the first metal material is an iron material, and the cold side wall has an electrically insulating coating, including one of a glass-ceramic sol-gel coating, a silicon (di) oxide coating, and a polysilazen coating; and
the second metal material is a titanium material, and the warm side wall has an electrically insulating anodised layer.

4. The module according to claim 1, wherein:
the first metal material is an aluminium material, and the cold side wall has an electrically insulating anodised layer; and
the second metal material is an iron material, and the warm side wall has an electrically insulating coating, including one of a glass-ceramic sol-gel coating, a silicon (di) oxide coating, a polysilazen coating.

5. The module according to claim 1, wherein the second heat expansion coefficient is smaller than the first heat expansion coefficient.

6. The module according to claim 5, wherein the first heat expansion coefficient is at least 25%, greater than the second heat expansion coefficient.

7. The module according to claim 2, wherein:
the first metal material is an austenitic iron material; and
the second metal material is one of a ferritic iron material, a ferritic steel material and a ferritic stainless steel material.

8. The module according to claim 1, wherein one of the cold side wall and the warm side wall has an electrically insulating anodised layer, and the other of the cold side wall and the warm side wall has the electrically insulating coating, wherein the conductor bridges are thermally sprayed onto one of the electrically insulating anodised layer and the electrically insulating coating.

9. The module according to claim 8, wherein the conductor bridges are sprayed on in multiple layers, a first layer of the multiple layers sprayed onto the one of the electrically insulating anodised layer and the electrically insulating coating consists of one of an aluminium material or of a titanium material, and an iron material, and a second layer of the multiple layers sprayed onto the first layer consists of one of a copper material and a nickel material.

10. The module according to claim 1, wherein the conductor bridges are configured as separate components and are glued onto the electrically insulated coating.

11. The module according to claim 1, wherein:
a metal layer is applied onto the electrically insulating coating at least in a region of the conductor bridges; and
the conductor bridges are one of galvanised onto the metal layer or configured as a separate component and soldered onto the metal layer.

12. The module according to claim 11, wherein one of:
the metal layer is galvanised onto the electrically insulating coating at least in the region of the conductor bridges;
the metal layer is printed on and burnt into the electrically insulating coating; or
the metal layer is applied to the the electrically insulating coating by one of a CVD method and a PVD method at least in the region of the conductor bridges.

13. The module according to claim 1, the conductor bridges are printed on and burnt into the electrically insulating coating.

14. The module according to claim 1, wherein the cold side wall along an edge region surrounding the module interior between a cold side and a warm side in a circumferential direction is directly soldered to the warm side wall.

15. The module according to claim 1, further comprising a separate connecting frame between the cold side wall and the warm side wall in a region of an edge region surrounding the module interior between a cold side and a warm side in a circumferential direction, the separate connecting frame being soldered to the cold side wall and to the warm side wall.

16. The module according to claim 1, wherein:
the cold side wall includes a cold side frame, which, along an edge region surrounding the module interior between a cold side and a warm side in a circumferential direction of the module housing, runs around in a closed manner and is attached to the cold side wall;
the warm side wall includes a warm side frame, which, along the edge region, runs around in a closed manner and is attached to the warm side wall; and
the cold side frame is soldered to the warm side frame.

17. The module according to claim 16, wherein at least one of:
the cold side frame is one of galvanized, printed on and burned, sprayed and glued onto the cold side wall; and
the warm side frame is one of galvanized, printed on and burned, sprayed and glued onto the warm side wall.

18. The module according to claim 3, wherein the conductor bridges are thermally sprayed onto one of the respective electrically insulating anodised layer and onto the respective electrically insulating coating.

19. The module according to claim 4, wherein the conductor bridges are thermally sprayed onto one of the respective electrically insulating anodised layer and onto the respective electrically insulating coating.

20. A thermoelectric module, comprising:
a metallic module housing that surrounds a module interior;
a plurality of thermoelectric elements arranged in the module interior; and
a plurality of conductor bridges arranged in the module interior for electrically interconnecting the thermoelectric elements;
wherein the module housing has a cold side including a cold side wall connected to a plurality of cold-side conductor bridges in a thermally conductive, electrically insulating and permanent manner;
wherein the module housing has a warm side including a warm side wall connected to a plurality of warm-side conductor bridges in a heat-conductive, electrically insulating and permanent manner;
wherein the thermoelectric elements extend between the cold-side conductor bridges and the warm-side conductor bridges;
wherein the cold side wall is formed from a first metal material and the warm side wall is formed from a second metal material;
wherein the first metal material has a first heat expansion coefficient and the second metal material has a second heat expansion coefficient;
wherein the second heat expansion coefficient is smaller than the first heat expansion coefficient;
wherein the cold side wall, along an edge region surrounding the module interior between the cold side and the warm side in a circumferential direction, is directly soldered to the warm side wall; and
wherein at least one of the first metal material and the second metal material is an iron material, at least one of the cold side wall and the warm side wall formed from the iron material having an electrically insulating coating, including one of a glass-ceramic sol-gel coating, a silicon oxide coating, and a polysilazen coating.
